(19) United States
(12) Patent Application Publication
(10) Pub. No.: US 2025/0118942 A1
(43) Pub. Date: Apr. 10, 2025

(54) SIDE WINDOW CAP AND SEMICONDUCTOR LIGHT EMITTING DEVICE

(71) Applicant: AGC INC., Tokyo (JP)

(72) Inventors: Nanako NISHIMOTO, Tokyo (JP); Ryota MURAKAMI, Tokyo (JP)

(73) Assignee: AGC INC., Tokyo (JP)

(21) Appl. No.: 18/979,851

(22) Filed: Dec. 13, 2024

Related U.S. Application Data
(63) Continuation of application No. PCT/JP2023/022823, filed on Jun. 20, 2023.

(30) Foreign Application Priority Data
Jun. 24, 2022 (JP) 2022-102030

(51) Int. Cl. H01S 5/02257; H01S 5/02218

(52) U.S. Cl. CPC H01S 5/02257; H01S 5/02218

(57) ABSTRACT

A side window cap is configured to cover and seal a light emitting element onto a substrate where the light emitting element is mounted. The side window cap has a cross sectional shape of an inverted recess having an upper wall portion, four side wall portions, and a lower opening. One of the four side wall portions is a window made of a transparent material. Three of the four side wall portions and the upper wall portion are made of glass ceramic. The transparent material and the glass ceramic are directly bonded.

### CROSS-REFERENCE TO RELATED APPLICATIONS

This is a bypass continuation of International Patent Application No. PCT/JP2023/022823, filed on Jun. 20, 2023, which claims priority to Japanese Patent Application No. 2022-102030, filed on Jun. 24, 2022. The contents of these applications are hereby incorporated by reference in their entireties.

### TECHNICAL FIELD

The present invention relates to a side window cap. The present invention also relates to a semiconductor light emitting device hermetically sealed with the side window cap.

### BACKGROUND ART

In recent years, electronic devices equipped with various light emitting elements such as laser diodes have been used in various fields. Some types of light emitting elements are required to be hermetically sealed, and therefore various sealing structures for sealing the light emitting elements have been studied in related art.

A light emission mode of the laser diode is divided into top emission and edge emission. The edge emission has an output higher than that of the top emission.

With respect to such edge emission, Patent Literature 1 discloses a light emitting device including a light emitting element configured to emit light, a first substrate on which the light emitting element is mounted, a second substrate configured to form a sealed space for the light emitting element between the first substrate and the second substrate, and a light extraction window for extracting the light emitted from the light emitting element, in which at least one of the first substrate and the second substrate has a cleavage property, and a window mounting surface on which the light extraction window is mounted is defined as a cleavage surface.

Patent Literature 2 discloses an electrical element mounting package including a flat substrate and one or more pedestals protruding from a frontside surface of the substrate and having a mounting surface on which an electrical element is mounted, in which the substrate and the pedestals are integrally formed from ceramics.

Patent Literature 3 discloses a light source device including a laser diode, a substrate having a major surface directly or indirectly supporting the laser diode, and a cap fixed to the substrate and configured to cover the laser diode, in which the cap has wall portions surrounding the laser diode and having an inner wall surface and an outer wall surface, the inner wall surface has at least a light entrance surface of laser light emitted from the laser diode and a first inclined surface, the outer wall surface has a light emission surface of the laser light emitted from the laser diode, at least one of the light entrance surface and the light emission surface is perpendicular to an optical axis of the laser light, and the first inclined surface is inclined toward the laser diode.

### CITATION LIST

### Patent Literature

Patent Literature 1: JP2009-289775A
Patent Literature 2: WO2018-030486
Patent Literature 3: JP2021-057459A

### SUMMARY OF INVENTION

### Technical Problem

However, the light emitting device described in Patent Literature 1 has an emission surface with an uneven structure, and the light extraction window is mounted later. Therefore, the second substrate and the light extraction window cannot be integrally molded, and a manufacturing process is complicated.

The electrical element mounting package described in Patent Literature 2 has a frame joined to all four sides of a glass serving as an emission surface, and therefore it is necessary to provide the pedestal protruding from the substrate and mount the electrical element on the pedestal. Therefore, a distance between a light emitting point and the emission surface cannot be reduced, and there is a limit to the demand for good heat dissipation and low-profile package.

In the light source device described in Patent Literature 3, the cap covering the laser diode is made entirely of glass, which causes leakage of laser light. Among them, since the laser light has a high linearity, light leakage from a surface facing the light emission surface is particularly concerned.

Accordingly, an object of the present invention is to provide a side window cap that allows a light emitting element to be directly mounted on a substrate without requiring a pedestal, allows integral molding, and prevents light leakage.

### Solution to Problem

In order to solve the above problem, an aspect of a side window cap according to the present embodiment is as follows.

A side window cap configured to cover and seal a light emitting element onto a substrate where the light emitting element is mounted, in which
the side window cap has a cross sectional shape of an inverted recess having an upper wall portion, four side wall portions, and a lower opening,
one of the four side wall portions is a window made of a transparent material,
three of the four side wall portions and the upper wall portion are made of glass ceramic, and
the transparent material and the glass ceramic are directly bonded.

An aspect of a semiconductor light emitting device according to the present embodiment is as follows.

A semiconductor light emitting device including:
a side window cap;
a substrate; and
a light emitting element provided on the substrate, in which
the side window cap includes a sealant layer on lower end surfaces of four side wall portions,
the sealant layer is a layer made of a metal film and has an Ag layer or an Au layer on an outermost surface thereof,
the side window cap and the substrate are integrated via the sealant layer and a gold-tin ring, and the light emitting element is hermetically sealed.

Note that, the side window cap has a cross sectional shape of an inverted recess having an upper wall portion, four side wall portions, and a lower opening, one of the four side wall portions is a window made of a transparent material, three of the four side wall portions and the upper wall portion are made of glass ceramic, and the transparent material and the glass ceramic are directly bonded.

### Advantageous Effects of Invention

According to the present invention, the light emitting element can be directly installed on the substrate without requiring a pedestal. Therefore, a distance between a light emitting point and an emission surface can be reduced, and good heat dissipation and low-profile package can also be implemented. According to the present invention, since the side window cap can be obtained by integral molding, productivity is excellent. Further, since an effect of preventing light leakage is also high, it is particularly suitable for use as a light emitting element for an edge emission type laser diode.

### BRIEF DESCRIPTION OF DRAWINGS

FIG. 1 is a schematic perspective view illustrating an aspect of a side window cap according to the present embodiment.

FIG. 2 is a cross-sectional view of the side window cap taken along a line A-A′ in FIG. 1.

FIG. 3 is a bottom view illustrating an aspect of the side window cap according to the present embodiment.

FIG. 4 is a cross-sectional view illustrating an aspect of the side window cap according to the present embodiment.

FIG. 5 is a bottom view illustrating an aspect of the side window cap according to the present embodiment.

FIG. 6 is a schematic cross-sectional view illustrating an aspect of a semiconductor light emitting device according to the present embodiment.

FIG. 7A and FIG. 7B are diagrams illustrating a part of a manufacturing process of the side window cap according to the present embodiment. FIG. 7A is a schematic top view illustrating an un-sintered multi-cavity glass ceramic precursor. FIG. 7B is a schematic side view illustrating the un-sintered multi-cavity glass ceramic precursor in FIG. 7A laminated with a glass ceramic precursor serving as a side wall portion on a side facing a side wall portion serving as a window.

FIG. 8A to FIG. 8C are diagrams illustrating a part of the manufacturing process of the side window cap according to the present embodiment. FIG. 8A is a schematic side view illustrating a glass ceramic obtained by sintering the glass ceramic precursor in FIG. 7B. FIG. 8B is a schematic side view illustrating the glass ceramic obtained in FIG. 8A on which a transparent material is mounted. FIG. 8C is a schematic top view illustrating dicing lines when singulating a multi-cavity side window cap.

### DESCRIPTION OF EMBODIMENTS

Hereinafter, the present invention is described in detail, but the present invention is not limited to the following embodiment and can be freely modified and implemented without departing from the gist of the present invention.

In the present description, “to” indicating a numerical range is used in the sense of including the numerical values set forth before and after the “to” as a lower limit value and an upper limit value.

The term “average coefficient of thermal expansion” or “coefficient of thermal expansion” in the present description refers to a value measured as an average value of a rate of elongation per 1° C. when heated in a range of 50° C. to 350° C.

### Side Window Cap

The side window cap 10 according to the present embodiment covers and seals a light emitting element onto a substrate where the light emitting element is mounted.

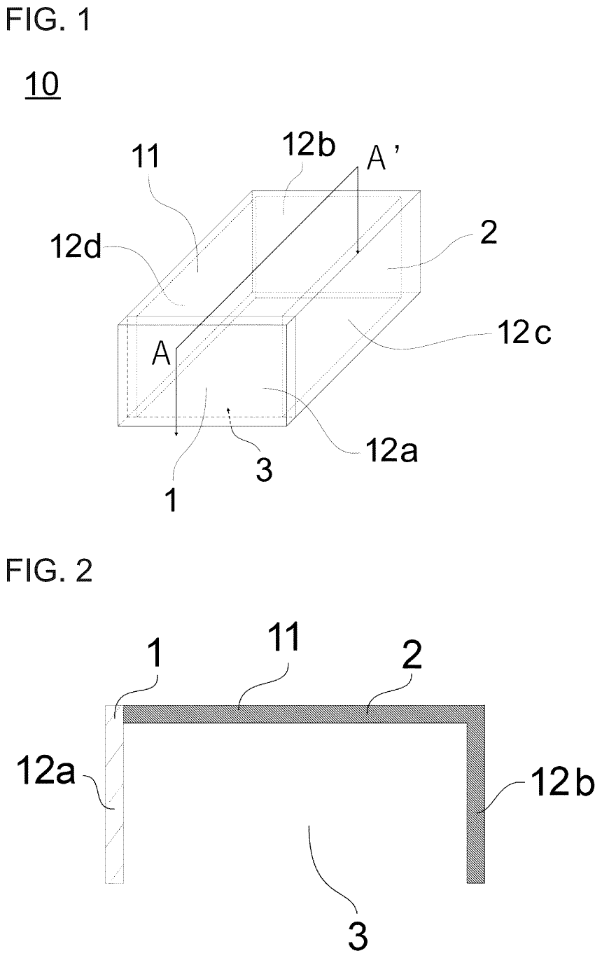

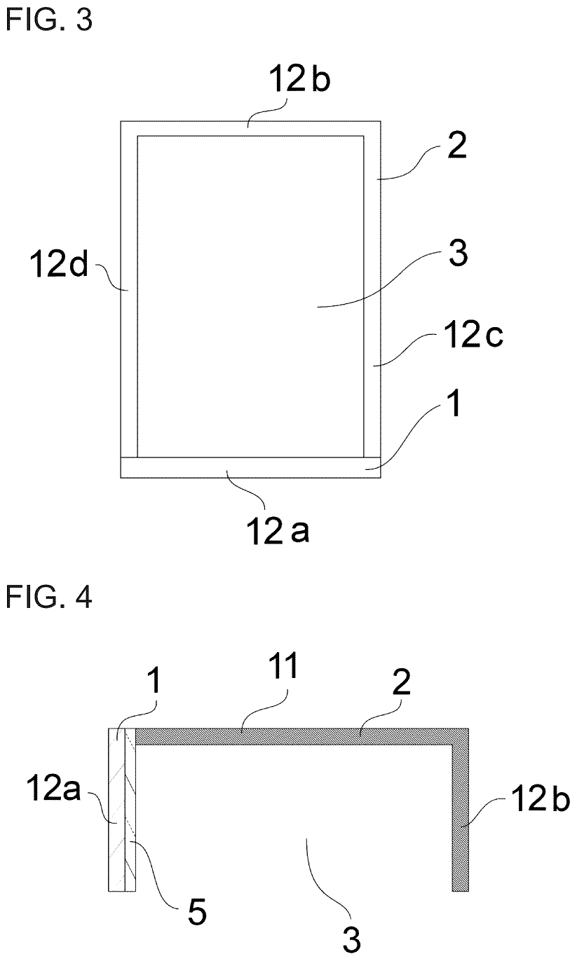

The side window cap 10 has a cross sectional shape of an inverted recess having an upper wall portion 11, four side wall portions 12a, 12b, 12c, and 12d, and a lower opening 3. As shown in FIG. 1 and FIG. 3, one side wall portion 12a of the four side wall portions is a window made of a transparent material 1. The remaining three side wall portions 12b, 12c, and 12d of the four side wall portions and the upper wall portion 11 are made of glass ceramic 2. Note that, FIG. 1 is a schematic perspective view illustrating an aspect of the side window cap according to the present embodiment, and FIG. 3 is a bottom view thereof.

It is preferable that the four side wall portions are perpendicular to the upper wall portion 11, but the four side wall portions do not have to be exactly 90° apart, and it is sufficient that the four side wall portions are regarded as perpendicular, taking into account manufacturing errors and the like. Specifically, the above-described “perpendicular” is sufficient if it is approximately perpendicular within a range of 90°±5°.

The transparent material 1 and the glass ceramic 2 are directly bonded. Direct bonding means a state where the transparent material 1 and the glass ceramic 2 are bonded without an adhesive layer of an organic material such as a resin layer interposed therebetween. Examples thereof include a heat melting method, a heat pressing method, ultrasonic bonding, bonding by laser heating, and optical contact. The direct bonding includes bonding via a bonding material such as a metal intermediate layer or glass frit, but the direct bonding without any bonding material is particularly preferred. Note that, FIG. 2 is a cross-sectional view taken along a line A-A′ in FIG. 1, and FIG. 2 illustrates an example in which the transparent material 1 and the glass ceramic 2 are directly bonded without a bonding material such as a metal intermediate layer or glass frit interposed therebetween.

Since the transparent material 1 and the glass ceramic 2 are directly bonded, an organic material such as a resin layer becomes unnecessary, and thus durability is excellent. An occurrence of a fine gap between the transparent material 1 and the glass ceramic 2 can be prevented, and high hermeticity can be implemented. Further, a detailed manufacturing method is described later, and a multi-cavity side window cap can be produced by direct bonding, and then a large number of side window caps can be obtained at once by cutting by dicing. Therefore, the manufacturing process is simplified and the productivity is excellent.

In the side window cap 10 according to the present embodiment, one side wall portion 12a of the four side wall portions is a window made of the transparent material 1, and thus a light extraction portion is a full-surface window. Therefore, high light extraction efficiency can be implemented as compared with an aspect in which the light extraction portion is small as in Patent Literature 1.

The remaining three side wall portions 12b, 12c, and 12d of the four side wall portions and the upper wall portion 11 are made of the glass ceramic 2. Glass ceramic has a Young's modulus higher than that of glass, prevents deformation of the transparent material 1, and stabilizes beam quality. Further, since a thickness of the side wall portion can be reduced, a volume of the lower opening 3 can be secured, and a semiconductor light emitting device can be downsized.

The transparent material 1 constitutes the side wall portion 12a serving as a window of the side window cap 10, and transmits light emitted from the light emitting element to be extracted to the outside. For example, it is preferable that the transparent material 1 is transparent in a visible region to a near infrared region.

Specifically, the transparent material 1 is preferably glass, silicon, or sapphire.

Silicon is preferably used as the transparent material 1 in terms of transmittance in an infrared region and heat resistance.

Sapphire is preferably used as the transparent material 1 in terms of mechanical strength and heat resistance.

Glass is preferably used as the transparent material 1 since it can be easily bonded directly to the glass ceramic 2.

When glass is used as the transparent material 1, glass used as a window material for a cavity in related art can be used.

From the viewpoint of preventing inhibition of insulating properties due to an increase in carbon residues during firing, and from the viewpoint of heat resistance when sealing with a substrate of a light emitting device, a glass transition temperature Tg of the glass is preferably 500° C. or higher, more preferably 515° C. or higher, and still more preferably 520° C. or higher, and the higher the glass transition temperature Tg, the more preferred. Note that, the glass transition temperature Tg of the glass in the present description is a temperature at a first inflection point in a differential thermal analysis (DTA) chart obtained by DTA.

From the viewpoint of preventing damage to a glass surface, a glass softening temperature Ts of the glass is preferably 700° C. or higher, more preferably 715° C. or higher, and still more preferably 730° C. or higher, and the higher the glass softening temperature Ts, the more preferred. Note that, the glass softening temperature Ts of the glass in the present description is a temperature at a fourth inflection point in the DTA chart.

An average coefficient of thermal expansion of the glass varies depending on an average coefficient of thermal expansion of the glass ceramic 2, and is preferably 20×10⁻⁷/° C. to 99×10⁻⁷/° C. Here, from the viewpoint of bringing the average coefficient of thermal expansion of the glass close to an average coefficient of thermal expansion of the substrate of the light emitting device to be mounted, the coefficient of thermal expansion of the glass is preferably 20×10⁻⁷/° C. or more, more preferably 22×10⁻⁷/° C. or more, and is preferably 99×10⁻⁷/° C. or less, and more preferably 92×10⁻⁷/° C. or less. Note that, a preferred combination of the upper and lower limit values is any.

As the glass satisfying the above characteristics, for example, soda lime glass, borosilicate silicate glass, or aluminosilicate glass can be used. From the viewpoint of processability, borosilicate glass or aluminosilicate glass is preferred.

The transparent material 1 may be appropriately subjected to a surface treatment in order to efficiently extract light to the outside.

For example, it is preferable that an antireflection film is formed on at least one of an outer surface and an inner surface of the transparent material 1. As illustrated in FIG. 4, it is more preferable that an antireflection film 5 is formed on an inner side of the transparent material 1, that is, on at least a partial region of a surface on a side where the light emitting element is mounted, and it is even more preferable that the antireflection film 5 is formed on at least a partial region of surfaces on both sides.

When the antireflection film 5 is formed on the inner side of the transparent material 1, it is preferable that the antireflection film 5 is formed on at least a part of a region where the transparent material 1 and the glass ceramic 2 are directly bonded. As illustrated in FIG. 4, the antireflection film 5 may be formed on an entire inner surface of the transparent material 1. In this case, the antireflection film 5 is formed over an entire region where the transparent material 1 and the glass ceramic 2 are directly bonded.

When the antireflection film 5 is formed on at least a part of the region where the transparent material 1 and the glass ceramic 2 are directly bonded, it is more preferable that the direct bonding does not involve any bonding material. In this case, an area of the window that can be effectively used is maximized, and loss of light emitted from a light emitting element 22 is minimized.

The antireflection film 5 may be any known one in the related art, and it is sufficient to reduce a reflectance of light having a design wavelength at least. Among them, a film made of an inorganic material is preferred from the viewpoint of maintaining good antireflection performance even in a heat treatment during manufacture of the side window cap 10. Examples of the film made of an inorganic material include a single-layer thin film and a dielectric multilayer film in which two or more dielectric layers having different refractive indices, such as SiO₂ and Ta₂O₅, are laminated.

An additional layer having any function may be formed on the transparent material 1 within a range not impairing the effects of the present invention. Examples thereof include a light diffusion layer and a conductive layer. It is preferable that the additional layer is made of an inorganic material from the viewpoint of hermeticity. The light diffusion layer may be directly formed by surface processing of the transparent material 1.

A thickness of the transparent material 1 is not particularly limited, and is preferably 200 μm to 1.5 mm, for example. Here, from the viewpoint of durability, the thickness is preferably 200 μm or more, more preferably 250 μm or more, and still more preferably 300 μm or more. On the other hand, from the viewpoint of transparency and miniaturization, the thickness of the transparent material 1 is preferably 1.5 mm or less, more preferably 1.2 mm or less, and still more preferably 1.1 mm or less. Note that, a preferred combination of the upper and lower limit values is any.

The glass ceramic 2 is obtained by dispersing a filler component in a glass matrix.

It is preferable that the upper wall portion 11 and the three side wall portions 12b, 12c, and 12d made of the glass ceramic 2 are integrated without any joint from the viewpoint of verticality. This can be implemented by a manufacturing method to be described later, that is, a method in which a plurality of glass ceramic precursors are laminated, desired holes are punched using a punching machine, and then sintering is performed, and a method in which a glass ceramic precursor is molded using a mold, and then sintering is performed. In this case, it is preferable that the upper wall portion 11 and the two side wall portions 12c and 12d are made of the same glass ceramic, and it is more preferable that the upper wall portion 11 and the three side wall portions 12b, 12c, and 12d are made of the same glass ceramic.

When the transparent material 1 is made of glass or sapphire and bonded to the glass ceramic 2 without involving a metal intermediate layer, glass frit, or the like, it is preferable that a glass softening temperature Ts of the glass matrix in the glass ceramic is lower than the glass transition temperature Tg of the transparent material 1. Accordingly, the temperature during direct bonding can be lowered, and damage to the surface of the transparent material 1 can be prevented.

A temperature difference between the glass transition temperature Tg of the transparent material 1 and the glass softening temperature Ts of the glass matrix is, for example, 30° C. to 200° C. Here, from the above viewpoint, the temperature difference is preferably 30° C. or higher, more preferably 35° C. or higher, and still more preferably 40° C. or higher. The temperature difference is not particularly limited, and is, for example, 200° C. or lower.

When the transparent material 1 is made of glass or sapphire and bonded to the glass ceramic 2 via glass frit, it is preferable that the glass softening temperature Ts of the glass frit is lower than the glass transition temperature Tg of the transparent material 1. Accordingly, the temperature during direct bonding can be lowered, and damage to the surface of the transparent material 1 can be prevented.

The glass frit is a sealing glass made of a low melting point glass, and any known glass may be used. For example, a low melting point glass such as tin-phosphate glass, bismuth glass, vanadium glass, lead glass, zinc borate alkali glass, and borosilicate glass can be suitably used. Among them, in consideration of adhesion, adhesion reliability, reliability of hermeticity, and influence on environment and human body, a low melting point glass made of tin-phosphate glass, bismuth glass, vanadium glass, or borosilicate glass is more preferred.

The specific glass softening temperature Ts of the glass matrix in the glass ceramic is preferably 450° C. to 1000° C. Here, the glass softening temperature Ts is preferably 1000° C. or lower, more preferably 950° C. or lower, and still more preferably 900° C. or lower. The glass softening temperature Ts of the glass matrix is preferably 450° C. or higher, more preferably 460° C. or higher, and still more preferably 470° C. or higher, from the viewpoint of preventing inhibition of insulation properties due to an increase in carbon residues during firing and from the viewpoint of heat resistance when sealing with the substrate. Note that, in the present description, the glass softening temperature Ts of the glass matrix is a temperature at a fourth inflection point in the DTA chart of the glass alone. A preferred combination of the upper and lower limit values is any.

The glass matrix may be any known one in the related art, and it is preferable that the glass matrix contains at least one of bismuth oxide and boron oxide, for example. That is, bismuth oxide glass or borosilicate glass is preferred.

The borosilicate glass may contain CeO₂, RO, R′₂O, R″₂O₃, R′″O₂, and the like in addition to SiO₂ and B₂O₃, and preferably contains ZnO, K₂O, and Na₂O.

Note that, in the present description, R is at least one selected from the group consisting of Zn, Ba, Sr, Mg, Ca, Fe, Mn, Cr, Sn, and Cu. R′is at least one selected from the group consisting of Li, Na, K, Cs, and Cu. R″ is at least one selected from the group consisting of Al, Fe, and La. R″ is at least one selected from the group consisting of Zr, Ti, and Sn.

The bismuth oxide glass may contain B₂O₃, CeO₂, SiO₂, RO, R′₂O, R″₂O₃ , and R′″O₂in addition to Bi₂O₃.

Note that, as long as the material can be directly bonded to the transparent material 1, ceramic may be used instead of glass ceramic. Examples of the ceramic include alumina and aluminum nitride.

The filler component may be any known one in the related art, and it is preferable that the filler component contains, for example, a low thermal expansion filler or a negative thermal expansion filler. By using the low thermal expansion filler or the negative thermal expansion filler, the side window cap 10 can maintain a good shape and adhesion to the transparent material 1 can also be made good. The filler may be used alone or in combination of two or more kinds thereof.

The low thermal expansion filler is a filler having a coefficient of thermal expansion of 0/° C. or more and 40×10⁻⁷/° C. or less, and examples thereof include zirconium oxide, silicon dioxide, and a mixture thereof. Examples of the mixture include cordierite (2MgO·2Al₂O₃·5SiO₂) which is a mixture of magnesium oxide, aluminum oxide, and silicon dioxide.

The negative thermal expansion filler is a filler whose coefficient of thermal expansion is a negative value, that is, less than 0/° C., and examples thereof include zirconium phosphate, β-eucryptite (Li₂O·Al₂O₃·2SiO₂), and zirconium tungstate (ZrW₂O₈).

A total volume fraction of the filler component in the glass ceramic is preferably 25 vol % to 65 vol %. Here, from the viewpoint of preventing an occurrence of cracks in the transparent material 1, the total volume fraction is, for example, preferably 25 vol % or more, more preferably 30 vol % or more, and still more preferably 35 vol % or more. From the viewpoint of obtaining good adhesion to the transparent material 1, the total volume fraction of the filler component is preferably 65 vol % or less, more preferably 63 vol % or less, and still more preferably 61 vol % or less. The above content may vary depending on a specific gravity of the filler, or the like. A preferred combination of the upper and lower limit values is any.

The filler component is an inorganic powder, a shape of the powder is not particularly limited, and examples thereof include spherical, flat, scaly, and fibrous.

The size of the powder of the filler component is not particularly limited, and a 50% particle size (D₅₀) is preferably 0.5 μm to 10 μm, for example. The 50% particle size (D₅₀) is preferably 0.5 μm or more, and more preferably 1 μm or more, and is preferably 10 μm or less, and more preferably 9 μm or less. Note that, the 50% particle size in the present description is a volume-based value measured using a laser diffraction/scattering particle size distribution measuring device. A preferred combination of the upper and lower limit values is any.

An average coefficient of thermal expansion of the glass ceramic 2 is preferably 15×10⁻⁷/° C. to 75×10⁻⁷/° C. Here, from the viewpoint of bringing the average coefficient of thermal expansion of the glass ceramic 2 close to the average coefficient of thermal expansion of the substrate in the light emitting device on which the side window cap 10 is mounted, the average coefficient of thermal expansion is, for example, preferably 15×10⁻⁷/° C. or more, more preferably 16×10⁻⁷/° C. or more, and still more preferably 17×10⁻⁷/° C. or more. The average coefficient of thermal expansion of the glass ceramic 2 varies depending on the average coefficient of thermal expansion of the transparent material 1, and the above-described average coefficient of thermal expansion is, for example, more preferably 75×10⁻⁷/° C. or less, still more preferably 70×10⁻⁷/° C. or less, and particularly preferably 65×10⁻⁷/° C. or less. A preferred combination of the upper and lower limit values is any.

From the viewpoint of preventing generation of cracks and separation of the transparent material 1 when the transparent material 1 and the glass ceramic 2 are directly bonded, an absolute value of a difference in average coefficient of thermal expansion between the transparent material 1 and the glass ceramic 2 is preferably 24×10⁻⁷/° C. or less, and more preferably 22×10⁻⁷/° C. or less, and the smaller the absolute value, the more preferred.

An upper surface, which includes the upper wall portion 11 of the side window cap 10 and an upper end surface of the side wall portion 12a serving as a window, is composed of the glass ceramic 2 and the transparent material 1. Similarly, side surfaces, which include the two side wall portions 12c and 12d excluding the side wall portion 12b that exists in a position facing the side wall portion 12a serving as a window and left and right end surfaces of the side wall portion 12a serving as a window, are also composed of the glass ceramic 2 and the transparent material 1.

However, the above upper surface and the two side surfaces can form a smooth surface without generating a step between the end surface portion of the transparent material 1 and the glass ceramic 2. This is because, in the side window cap 10 according to the present embodiment, after the transparent material 1 and the glass ceramic 2 are directly bonded, a large number of side window caps 10 can be obtained by cutting a multi-cavity side window cap by dicing.

In this way, the side window cap 10 can be obtained by directly bonding the transparent material 1 to the glass ceramic 2 first and then performing cutting, without later attaching the transparent material 1, which is useful not only from the viewpoint of productivity but also from the viewpoint of smoothness of the entire surface of the side window cap.

For the above reason, a maximum height roughness Rz of each of the outer surfaces of the side window cap including the upper surface and the two side surfaces can be 50 μm or less. The maximum height roughness Rz may be 47 μm or less, or may be 45 μm or less.

When manufacturing a side window cap by later attaching or later inserting the transparent material 1 serving as a window into a singulated cavity, the maximum height roughness Rz is generally more than 150 μm.

Note that, in the present description, the maximum height roughness Rz is an index of surface roughness, and is a sum of the height of the highest peak and the depth of the deepest valley in a contour curve of the reference length, and is determined in accordance with JIS B 0601:2001. Specifically, the maximum height roughness Rz is a value obtained by measuring a measurement length of 3 mm with a surface roughness and contour shape measuring instrument Surfcom at a cutoff wavelength of 0.8 mm.

As illustrated in FIG. 3, the lower opening 3 is a space surrounded by the upper wall portion 11 and the four side wall portions 12a, 12b, 12c, and 12d, which are composed of the transparent material 1 and the glass ceramic 2. When the side window cap 10 according to the present embodiment is sealed with the substrate, a space (a gap) is formed to accommodate the light emitting element.

The lower opening 3 is generally in a shape of a quadrangular prism, and may be in any shape other than a quadrangular prism as desired, and may be in a shape different from an outer shape of the side window cap 10. Examples thereof include a semi-cylindrical shape and a multi-prism shape. From the viewpoint of ease of processing, the shape of the lower opening 3 is preferably a quadrangular prism shape, that is, a hexagonal shape or a semi-cylindrical shape.

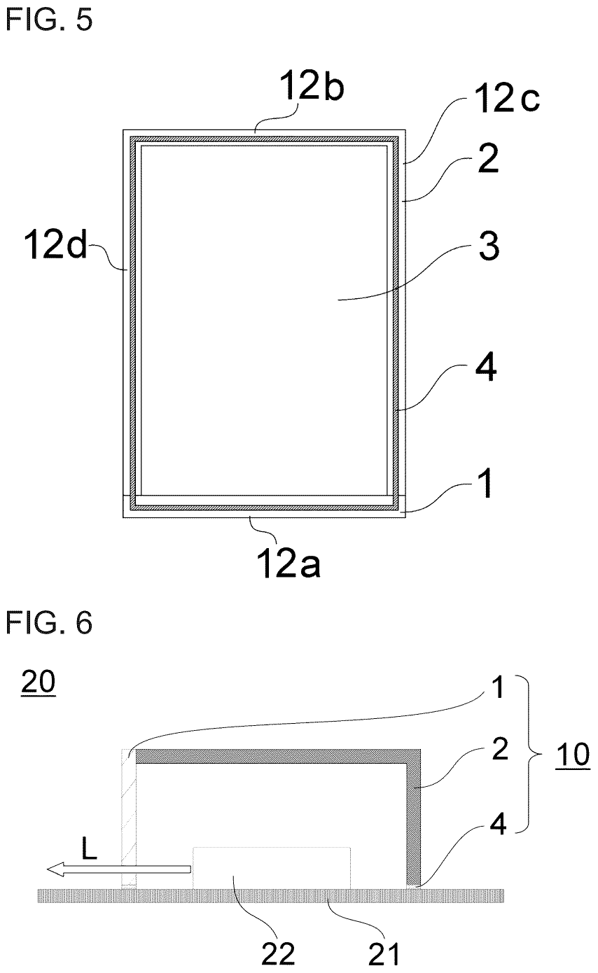

As illustrated in FIG. 5, it is preferable that the side window cap 10 includes a sealant layer 4 on lower end surfaces of the four side wall portions. The lower end surfaces of the four side wall portions mean end surfaces on a lower opening 3 side.

As illustrated in FIG. 6, the sealant layer 4 is effective when the side window cap 10 is sealed to the substrate 21 on which the light emitting element 22 is mounted so as to cover the light emitting element 22 to obtain a semiconductor light emitting device 20.

In FIG. 5, a width of the sealant layer 4 is narrower than widths of the lower end surfaces of the four side wall portions. Alternatively, the width of the sealant layer 4 may be the same as the width of the lower end surfaces of the four side wall portions, or may be any as long as sealing can be provided.

The sealant layer 4 is preferably a layer made of a metal film or glass frit.

When the sealant layer 4 is a layer made of a metal film, the side window cap 10 and the substrate 21 can be hermetically sealed by sealing via a metal ring. Examples of the metal ring include a gold (Au)-tin (Sn) gold-tin ring, a tin (Sn)-antimony (Sb) ring, and a tin (Sn)-silver (Ag)-copper (Cu) ring. From the viewpoint of sealing properties, a gold-tin ring is more preferred.

The layer made of a metal film preferably has a layer of a metal coating containing one or more selected from the group consisting of Au, Ag, Cu, and an Au-Sn alloy on the outermost surface thereof, and more preferably has an Ag layer or an Au layer, from the viewpoint of sealing properties when sealing via a metal ring. The layer made of a metal film may further include a coating of Ni, Ti, Pd, Pt, Cu or the like as an undercoat of the metal coating layer.

When the sealant layer 4 is a layer made of glass frit, the side window cap 10 and the substrate 21 can be hermetically sealed by sealing by heating.

The glass frit is a sealing glass made of a low melting point glass, and any known glass may be used. For example, a low melting point glass such as tin-phosphate glass, bismuth glass, vanadium glass, lead glass, and zinc borate alkali glass is suitably used. Among them, in consideration of adhesion, adhesion reliability, reliability of hermeticity, and influence on environment and human body, a low melting point glass made of tin-phosphate glass, bismuth glass, or vanadium glass is more preferred.

The glass frit may further contain an inorganic filler such as an electromagnetic wave absorber or a low thermal expansion filler.

### Semiconductor Light Emitting Device

The semiconductor light emitting device 20 according to the present embodiment includes the side window cap 10, the substrate 21, and the light emitting element 22 provided on the substrate 21. The light emitting element 22 is hermetically sealed by integrating the side window cap 10 with the substrate 21 via the sealant layer 4 on the lower end surfaces of the four side wall portions of the side window cap 10.

As the side window cap 10, those described in the above <Side Window Cap >can be used, and a preferred embodiment is also the same.

The sealant layer 4 is preferably a layer made of a metal film or a layer made of glass frit, and more preferably a layer made of a metal film, and more preferably has an Ag layer or an Au layer on the outermost surface thereof. It is preferable that the side window cap 10 and the substrate 21 are integrated with each other via a gold-tin ring and the sealant layer 4, which is a layer made of such a metal film.

In the semiconductor light emitting device 20, the substrate 21 is not particularly limited as long as it is insulating, and is preferably a ceramic substrate from the viewpoint of heat dissipation. The ceramic substrate is preferably, for example, an aluminum nitride (AIN) substrate, an alumina (Al₂O₃) substrate, or a low temperature co-fired ceramics (LTCC) substrate.

In the semiconductor light emitting device 20, the light emitting element 22 of both top emission and edge emission can be used. From the viewpoint of further obtaining the effect of the present invention, the edge emission is preferable, that is, emission light L from the light emitting element 22 is preferably in a horizontal direction as illustrated in FIG. 6, and examples thereof include a laser diode (LD). A window made of the transparent material 1 is disposed on a side where light is emitted from the light emitting element 22.

Since the laser diode has a high light linearity, light leakage from the side wall portion 12b facing the side wall portion 12a serving as a window is particularly concerned. However, in the semiconductor light emitting device 20 according to the present embodiment, since the side wall portion 12b is made of glass ceramic, the concern of light leakage is unnecessary.

### Method for Manufacturing Side Window Cap

A method for manufacturing the side window cap 10 according to the present embodiment is not particularly limited as long as the side window cap 10 having features described in <Side Window Cap>can be obtained.

An example of the method for manufacturing the side window cap 10 according to the present embodiment is described below. Note that, the following manufacturing method is a method in which a multi-cavity side window cap is obtained and then cut by dicing to obtain individual side window caps. Although such a method is excellent in productivity, it does not exclude a method for manufacturing side window caps one by one.

A method for manufacturing glass, silicon, or sapphire serving as the transparent material 1 is not particularly limited, and the transparent material 1 may be manufactured or may be commercially available. A layer having a function such as an antireflection film may be provided on the transparent material 1 as desired.

A method for producing the glass ceramic 2 is not particularly limited, and for example, the glass ceramic 2 can be obtained by molding and sintering a glass ceramic precursor which is a mixture of glass powder serving as a glass matrix and a filler component. Specific examples thereof include a method in which the above precursor is formed into a sheet called a green sheet and sintered.

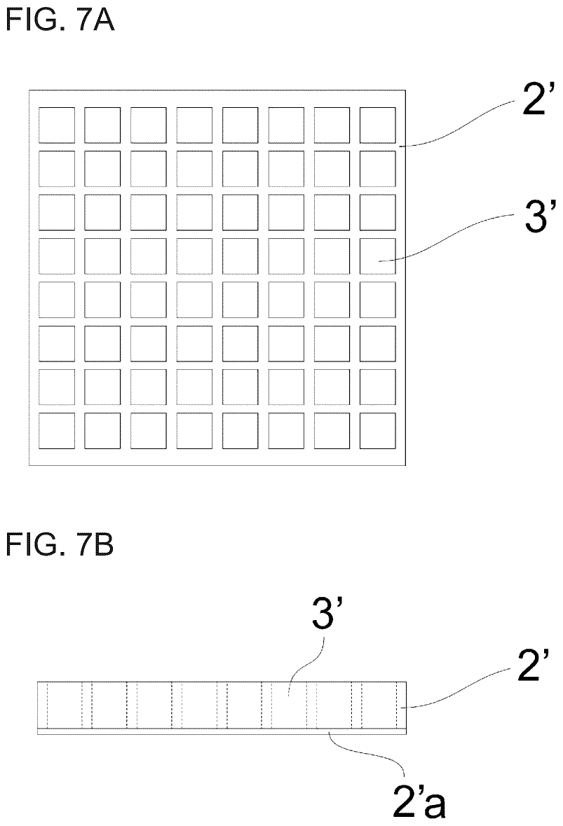

When manufacturing the glass ceramic 2 with using a green sheet as a glass ceramic precursor, a plurality of green sheets are laminated to a desired height. Thereafter, as illustrated in FIG. 7A, a plurality of holes 3′ having a desired size and shape are formed using a punching machine, thereby obtaining a panel of an un-sintered multi-cavity glass ceramic precursor 2′ serving as the upper wall portion 11 and the two facing side wall portions 12c and 12d.

Separately from the above, a plurality of green sheets are laminated so as to have a desired height, thereby obtaining a panel of the un-sintered glass ceramic precursor 2′a serving as the side wall portion 12b on a side facing the side wall portion 12a serving as a window.

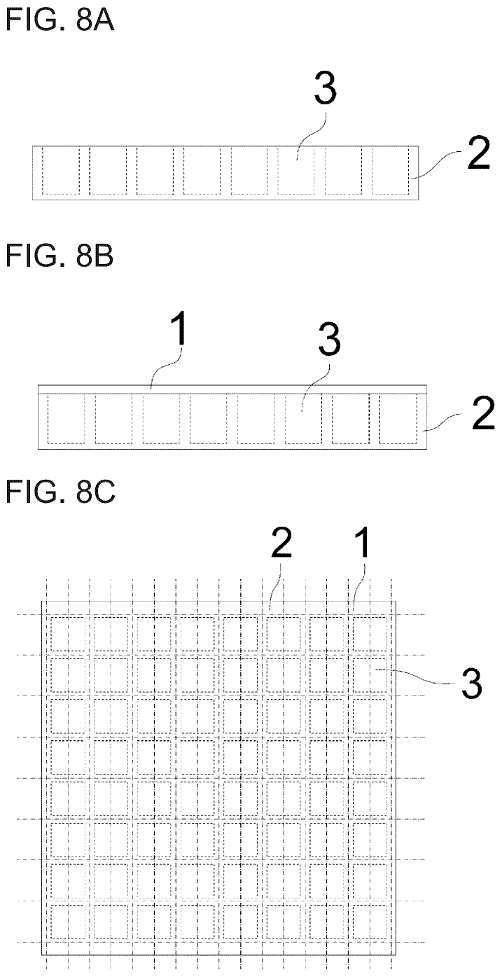

As illustrated in FIG. 7B, the two panels obtained as described above are laminated and sintered, thereby obtaining the multi-cavity glass ceramic 2 having the upper wall portion 11 and the three side wall portions 12b, 12c, and 12d without any joint, as illustrated in FIG. 8A

Next, as illustrated in FIG. 8B, the transparent material 1 is mounted on the obtained glass ceramic 2 such that end surfaces of the glass ceramic serving as the upper wall portion 11 and the two facing side wall portions 12c and 12d are in contact with the transparent material 1 to perform direct bonding, thereby obtaining a multi-cavity side window cap.

Examples of the direct bonding include a heat melting method, a heat pressing method, ultrasonic bonding, bonding by laser heating, and optical contact.

Before directly bonding the transparent material 1 and the glass ceramic 2, end surfaces of the upper wall portion 11 and the two facing side wall portions 12c, 12d of the glass ceramic 2 may be polished to reduce a surface roughness Ra. A surface roughness of the transparent material 1 may also be reduced by polishing or the like.

The surface roughness Ra of the end surfaces and the surface of the transparent material 1 is preferably 0.2 μm or less, and more preferably 0.1 μm or less, from the viewpoint of bondability after direct bonding. The surface roughnesses Ra of each end surface and the transparent material 1 do not need to be the same. Note that, in the present description, the surface roughness Ra is a value measured in accordance with JIS B 0601:2001.

Thereafter, dot-dashed lines illustrated in FIG. 8C are used as dicing lines for cutting, thereby obtaining a plurality of singulated side window caps 10. A cutting method is not particularly limited, and may be laser dicing using laser light, blade dicing using a dedicated blade, or a combination of a plurality of cutting methods. Among them, blade dicing is preferred from the viewpoint of cutting ability.

When the sealant layer 4 is further provided on the side window cap 10, among the dot-dashed lines illustrated in FIG. 8C, only a dot-dashed line in a direction including a center line of the lower opening 3 is used as a dicing line for cutting. If desired, a cut surface is polished, and then the sealant layer 4 is formed by a known method in the related art using a known sealing material in the related art.

The sealant layer 4 can be formed by a printing method, a coating method using a dispenser, a dipping method, a laser metal deposition method, a method using a solder wire, or the like.

Thereafter, cutting is performed again along another dot-dashed line among the dot-dashed lines illustrated in FIG. 8C as a dicing line, thereby obtaining a plurality of singulated side window caps 10.

Note that, although the method for obtaining a side window cap by using a green sheet as a glass ceramic precursor has been described above, a multi-cavity glass ceramic may be obtained by using a mold for molding. In this case, similar to the above, a transparent material is directly bonded and then cut to obtain a plurality of singulated side window caps 10.

Although the side window cap and the manufacturing method therefor according to the present embodiment have been described in detail above, other aspects of the present embodiment are as follows.
[1] A side window cap configured to cover and seal a light emitting element onto a substrate where the light emitting element is mounted,
in which the side window cap has a cross sectional shape of an inverted recess having an upper wall portion, four side wall portions, and a lower opening,
one of the four side wall portions is a window made of a transparent material,
three of the four side wall portions and the upper wall portion are made of glass ceramic, and
the transparent material and the glass ceramic are directly bonded.
[2] The side window cap according to the above [1], in which outer surfaces of the side window cap all have a maximum height roughness Rz of 50 μm or less.
[3] The side window cap according to the above [1] or [2], in which the transparent material is glass, silicon, or sapphire.
[4] The side window cap according to any one of the above [1] to [3], in which an absolute value of a difference in average coefficient of thermal expansion from 50° C. to 350° C. between the transparent material and the glass ceramic is 24×10⁻⁷/° C. or less.
[5] The side window cap according to any one of the above [1] to [4], in which an antireflection film is formed on at least one of an outer surface and an inner surface of the transparent material.
[6] The side window cap according to any one of the above [1] to [5], in which an antireflection film is formed on at least a partial region of an inner surface of the transparent material, and the antireflection film is also formed on at least a part of the directly bonded region.
[7] The side window cap according to any one of the above [1] to [6], including a sealant layer on lower end surfaces of the four side wall portions.
[8] The side window cap according to the above [7], in which the sealant layer is a layer made of a metal film and has an Ag layer or an Au layer on an outermost surface thereof.
[9] A semiconductor light emitting device including:
the side window cap according to the above [8];
a substrate; and
a light emitting element provided on the substrate,
in which the side window cap and the substrate are integrated via the sealant layer and a gold-tin ring, and the light emitting element is hermetically sealed.

### EXAMPLES

Hereinafter, the present invention is described in detail with reference to Examples, but the present invention is not limited thereto. Note that, Example 1 to Example 3 are Inventive Examples, and Example 4 is Comparative Example.

### Example 1

As a transparent material, a 50 mm×50 mm×0.7 mmt glass plate (EN-A1,manufactured by AGC Inc.) made of alkali-free borosilicate glass was prepared. The glass has a glass transition temperature Tg of 710° C. and a coefficient of thermal expansion of 39×10⁻⁷/° C. from 50° C. to 350° C.

As a glass ceramic precursor, an inorganic powder was obtained by blending and mixing 52 vol % of glass powder (ASF-1109, manufactured by AGC Inc., glass softening temperature Ts=537° C.) as a glass matrix and 48 vol % of zirconium phosphate (Ultea (registered trademark) WH2, manufactured by Toagosei Co., Ltd.) as a filler component. The inorganic powder was mixed with a plasticizer and a binder in the presence of an organic solvent to prepare a slurry. The slurry was applied onto a polyethylene terephthalate (PET) film by a doctor blade method and dried to produce a green sheet. A thickness of each green sheet was 200 μm.

Thirty-six green sheets were laminated, and a punching machine was used to punch 8×8 square holes of 4.0 mm×4.0 mm to obtain an un-sintered 64-connected multi-cavity panel. The panel was sintered at 600°° C. to obtain a multi-cavity glass ceramic panel having a thickness of 6.3 mm and 8×8 square holes of 3.4 mm×3.4 mm. The obtained glass ceramic has a coefficient of thermal expansion of 36×10⁻⁷/° C. from 50°° C. to 350° C.

A surface of the glass ceramic having an opening with a square hole was polished to have a surface roughness Ra of 0.1 μm or less.

Next, the multi-cavity glass ceramic was disposed on a glass plate made of the alkali-free borosilicate glass, which is a transparent material, such that the surface of the glass ceramic having the opening was in contact with the glass plate, and then direct bonding was performed by sintering at 600° C. to obtain a multi-cavity side window cap.

For the multi-cavity side window cap, 16 rows of 8-cavity side window caps each having 1×8 connected squares were cut from the glass plate side using a blade dicing. As shown in FIG. 8C, dicing lines were 17 in total, including center lines of lower openings and center lines of connecting portions between the openings that were parallel to the center lines of the lower openings.

Cut surfaces formed by the dicing were lower end surfaces of four side wall portions of a cavity with a window frame, and thus a silver paste (US-202A manufactured by Daiken Chemical Industry Co., Ltd.) was screen-printed on such cut surfaces. For the screen printing, a screen plate having a mesh size of 325 and an emulsion thickness of 10 μm was used. A pattern of the screen plate was a frame shape having a line width of 0.4 mm.

After screen printing, the resultant was dried at 70° C. for 30 minutes and then fired at 450° C. for 30 minutes to form a sealant layer having a thickness of 7 μm and a line width of 0.4 mm on the lower end surfaces of the four side wall portions.

Next, the multi-cavity side window cap was cut again along a total of nine center lines of the connecting portions between the openings, each of which was perpendicular to the dicing line used in first cutting, thereby performing singulating to obtain 128 side window caps each having a sealant layer formed thereon.

Dimensions of each side window cap were 4.8 mm×6.9 mm for the upper surface, with 0.7 mm of the 6.9 mm being for the upper end surface of the glass forming the side wall portion 12a serving as a window, and 6.2 mm being for the upper wall portion 11 made of glass ceramic. The side surface serving as a window and the facing side surface both had a height of 2.2 mm and a width of 4.8 mm. The remaining two side surfaces each had a height of 2.2 mm and a width of 6.9 mm, with 0.7 mm of the 6.9 mm being for the left and right end surfaces of the glass forming the side wall portion 12a serving as a window, and 6.2 mm being for the side wall portions 12c and 12d made of glass ceramic. Both the glass ceramic and the glass had a thickness of 0.7 mm, and dimensions of the lower opening 3 were 3.4 mm×5.5 mm and 1.5 mm high.

On the other hand, an aluminum nitride (AIN) substrate (AN-170, manufactured by MARUWA CO., LTD., 7.5 mm×7.5 mm×0.635 mmt) having a Au/Pt/Ti coating formed on the surface thereof was prepared. The side window cap having the sealant layer formed thereon was sealed via a gold-tin ring to a surface of the substrate on which the Au/Pt/Ti coating was formed. Sealing conditions were a nitrogen environment, 280° C., and 60 seconds.

A He bombardment leak test was performed on the sealed substrate-attached side window cap, and a leak amount was 3.0×10⁻¹⁰ Pa·m³/ s, confirming that there was no leak and that hermeticity was good.

### Example 2

As a transparent material, a 50 mm×50 mm×0.7 mmt glass plate (D263 (registered trademark) T eco, manufactured by SCHOTT) made of borosilicate glass was prepared. The glass has a glass transition temperature Tg of 566° C. and a coefficient of thermal expansion of 72×10⁻⁷/° C. from 50° C. to 350° C. An antireflection film was formed on both surfaces of the glass by vapor deposition.

As a glass ceramic precursor, an inorganic powder was obtained by blending and mixing 75 vol % of glass powder (KF9173, manufactured by AGC Inc., glass softening temperature Ts=480° C.) as a glass matrix and 25 vol % of cordierite (manufactured by MARUSU GLAZE Co., Ltd.) as a filler component. The inorganic powder was mixed with a plasticizer and a binder in the presence of an organic solvent to prepare a slurry. The slurry was applied onto a polyethylene terephthalate (PET) film by a doctor blade method and dried to produce a green sheet. A thickness of each green sheet was 200 μm.

Thirty-six green sheets were laminated, and a punching machine was used to punch 8×8 square holes of 4.0 mm×4.0 mm to obtain an un-sintered 64-connected multi-cavity panel. The panel was sintered at 600° C. to obtain a multi-cavity glass ceramic panel having a thickness of 6.3 mm and 8×8 square holes of 3.4 mm×3.4 mm. The obtained glass ceramic has a coefficient of thermal expansion of 68×10−7/° C. from 50° C. to 350° C.

A surface of the glass ceramic having an opening with a square hole was polished to have a surface roughness Ra of 0.1 μm or less.

Next, the multi-cavity glass ceramic was disposed on a glass plate made of the borosilicate glass, which is a transparent material, such that the surface of the glass ceramic having an opening was in contact with the glass plate, and then direct bonding was performed by sintering at 550° C. to obtain a multi-cavity side window cap.

For the multi-cavity side window cap, 16 rows of 8-cavity side window caps each having 1×8 connected squares were cut from the glass plate side using a blade dicing. As shown in FIG. 8C, dicing lines were 17 in total, including center lines of lower openings and center lines of connecting portions between the openings that were parallel to the center lines of the lower openings.

Cut surfaces formed by the dicing were lower end surfaces of four side wall portions of a cavity with a window frame, and thus a silver paste (US-202A manufactured by Daiken Chemical Industry Co., Ltd.) was screen-printed on such cut surfaces. For the screen printing, a screen plate having a mesh size of 325 and an emulsion thickness of 10 μm was used. A pattern of the screen plate was a frame shape having a line width of 0.4 mm.

After screen printing, the resultant was dried at 70° C. for 30 minutes and then fired at 450° C. for 30 minutes to form a sealant layer having a thickness of 7 μm and a line width of 0.4 mm on the lower end surfaces of the four side wall portions.

Next, the multi-cavity side window cap was cut again along a total of nine center lines of the connecting portions between the openings, each of which was perpendicular to the dicing line used in first cutting, thereby performing singulating to obtain 128 side window caps each having a sealant layer formed thereon.

Dimensions of each side window cap were 4.8 mm×6.9 mm for the upper surface, with 0.7 mm of the 6.9 mm being for the upper end surface of the glass forming the side wall portion 12a serving as a window, and 6.2 mm being for the upper wall portion 11 made of glass ceramic. The side surface serving as a window and the facing side surface both had a height of 2.2 mm and a width of 4.8 mm. The remaining two side surfaces each had a height of 2.2 mm and a width of 6.9 mm, with 0.7 mm of the 6.9 mm being for the left and right end surfaces of the glass forming the side wall portion 12a serving as a window, and 6.2 mm being for the side wall portions 12c and 12d made of glass ceramic. Both the glass ceramic and the glass had a thickness of 0.7 mm, and dimensions of the lower opening 3 were 3.4 mm×5.5 mm and 1.5 mm high.

### Example 3

As a transparent material, a 50 mm×50 mm×0.7 mmt plate (mirror-polished on both sides) made of sapphire was prepared. The sapphire has a coefficient of thermal expansion of 76×10−7/° C. from 50° C. to 350° C.

As a glass ceramic precursor, an inorganic powder was obtained by blending and mixing 42 vol % of glass powder (ASF-1860, manufactured by AGC Inc., glass softening temperature Ts =830° C.) as a glass matrix and 58 vol % of aluminum oxide as a filler component. An appropriate amount of paraffine was added to the inorganic powder, and the mixture was heated and pressed in a mold to obtain a multi-cavity compact glass ceramic having a thickness of 6.3 mm and 8×8 square holes of 3.2 mm×3.2 mm.

A surface of the glass ceramic having an opening with a square hole was polished to have a surface roughness Ra of 0.1 μm or less.

The polished glass ceramic was printed with glass frit and fired at 580° C. The same glass frit was printed on the sapphire plate and fired.

Next, the multi-cavity glass ceramic was disposed on a plate made of the sapphire, which is a transparent material, such that the surface of the glass ceramic having an opening was in contact with the sapphire plate, and then direct bonding was performed by sintering at 680° C. to obtain a multi-cavity side window cap.

For the multi-cavity side window cap, 16 rows of 8-cavity side window caps each having 1×8 connected squares were cut from the sapphire plate side using a blade dicing. As shown in FIG. 8C, dicing lines were 17 in total, including center lines of lower openings and center lines of connecting portions between the openings that were parallel to the center lines of the lower openings.

Cut surfaces formed by the dicing were lower end surfaces of four side wall portions of a cavity with a window frame, and thus a silver paste (US-202A manufactured by Daiken Chemical Industry Co., Ltd.) was screen-printed on such cut surfaces. For the screen printing, a screen plate having a mesh size of 325 and an emulsion thickness of 10 μm was used. A pattern of the screen plate was a frame shape having a line width of 0.4 mm.

After screen printing, the resultant was dried at 70° C. for 30 minutes and then fired at 450° C. for 30 minutes to form a sealant layer having a thickness of 7 μm and a line width of 0.4 mm on the lower end surfaces of the four side wall portions.

Next, the multi-cavity side window cap was cut again along a total of nine center lines of the connecting portions between the openings, each of which was perpendicular to the dicing line used in first cutting, thereby performing singulating to obtain 128 side window caps each having a sealant layer formed thereon.

Dimensions of each side window cap were 4.8 mm×6.9 mm for the upper surface, with 0.7 mm of the 6.9 mm being for the upper end surface of the sapphire forming the side wall portion 12a serving as a window, and 6.2 mm being for the upper wall portion 11 made of glass ceramic. The side surface serving as a window and the facing side surface both had a height of 2.2 mm and a width of 4.8 mm. The remaining two side surfaces each had a height of 2.2 mm and a width of 6.9 mm, with 0.7 mm of the 6.9 mm being for the left and right end surfaces of the sapphire forming the side wall portion 12a serving as the window, and 6.2 mm being for the side wall portions 12c and 12d made of glass ceramic. Both the glass ceramic and the sapphire had a thickness of 0.7 mm, and dimensions of the lower opening 3 were 3.4 mm×5.5 mm and 1.5 mm high.

### Example 4

As a transparent material, a 50 mm×50 mm×0.7 mmt plate (mirror-polished on both sides) made of sapphire was prepared. The sapphire has a coefficient of thermal expansion of 76×10⁻⁷/° C. from 50° C. to 350° C.

As a glass ceramic precursor, an inorganic powder was obtained by blending and mixing 52 vol % of glass powder (ASF-1109, manufactured by AGC Inc., glass softening temperature Ts=537° C.) as a glass matrix and 48 vol % of zirconium phosphate (Ultea (registered trademark) WH2, manufactured by Toagosei Co., Ltd.) as a filler component. The inorganic powder was mixed with a plasticizer and a binder in the presence of an organic solvent to prepare a slurry. The slurry was applied onto a polyethylene terephthalate (PET) film by a doctor blade method and dried to produce a green sheet. A thickness of each green sheet was 200 μm.

Thirty-six green sheets were laminated, and a punching machine was used to punch 8×8 square holes of 4.0 mm×4.0 mm to obtain an un-sintered 64-connected multi-cavity panel. The panel was sintered at 600° C. to obtain a multi-cavity glass ceramic panel having a thickness of 6.3 mm and 8×8 square holes of 3.4 mm×3.4 mm. The obtained glass ceramic has a coefficient of thermal expansion of 36×10⁻⁷/° C. from 50° C. to 350° C.

A surface of the glass ceramic having an opening with a square hole was polished to have a surface roughness Ra of 0.1 μm or less.

Next, the multi-cavity glass ceramic was disposed on the sapphire plate, which is a transparent material, such that the surface of the glass ceramic having an opening was in contact with the sapphire plate, and then firing was performed at 600° C. to attempt direct bonding, but bonding was not possible due to a difference in coefficient of thermal expansions between the sapphire and the glass ceramic.

Although the present invention has been described in detail with reference to specific embodiments, it is apparent to those skilled in the art that various changes and modifications can be made without departing from the spirit and scope of the present invention. The present application is based on a Japanese Patent Application (Japanese Patent Application No. 2022-102030) filed on Jun. 24, 2022, the content of which is incorporated herein by reference.

### REFERENCE SIGNS LIST

1 transparent material
2 glass ceramic
2′, 2′a glass ceramic precursor
3 lower opening
3′ hole
4 sealant layer
5 antireflection film
10 side window cap
11 upper wall portion
12, 12a, 12b, 12c side wall portion
20 semiconductor light emitting device
21 substrate
22 light emitting element
L emission light

1. A side window cap configured to cover and seal a light emitting element onto a substrate where the light emitting element is mounted,
wherein the side window cap has a cross sectional shape of an inverted recess having an upper wall portion, four side wall portions, and a lower opening,
one of the four side wall portions is a window made of a transparent material,
three of the four side wall portions and the upper wall portion are made of glass ceramic, and
the transparent material and the glass ceramic are directly bonded.

2. The side window cap according to claim 1, wherein outer surfaces of the side window cap all have a maximum height roughness Rz of 50 μm or less.

3. The side window cap according to claim 1, wherein the transparent material is glass, silicon, or sapphire.

4. The side window cap according to claim 1, wherein an absolute value of a difference in average coefficient of thermal expansion from 50° C. to 350° C. between the transparent material and the glass ceramic is 24×10⁻⁷/° C. or less.

5. The side window cap according to claim 1, wherein an antireflection film is formed on at least one of an outer surface and an inner surface of the transparent material.

6. The side window cap according to claim 1, wherein an antireflection film is formed on at least a partial region of an inner surface of the transparent material, and the antireflection film is also formed on at least a part of the directly bonded region.

7. The side window cap according to claim 1, comprising a sealant layer on lower end surfaces of the four side wall portions.

8. The side window cap according to claim 7, wherein the sealant layer is a layer made of a metal film and has an Ag layer or an Au layer on an outermost surface thereof. 9 A semiconductor light emitting device comprising.
the side window cap according to claim 8;
a substrate; and
a light emitting element provided on the substrate.
wherein the side window cap and the substrate are integrated via the sealant layer and a gold-tin ring, and the light emitting element is hermetically sealed.
